(19) United States
(12) Patent Application Publication
(10) Pub. No.: US 2003/0186555 A1
(43) Pub. Date: Oct. 2, 2003

(54) Utilizing chemical dry etching for forming rounded corner in shallow trench isolation process

(76) Inventors: Ming-Chung Liang, Taipei (TW); Shtuh-Sheng Yu, Keelung (TW); Chun-Hung Lee, Jungli City (TW); Shin-Yi Tsai, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/105,240

(22) Filed: Mar. 26, 2002

(51) Int. Cl. H01L 21/302; H01L 21/461

(52) U.S. Cl. 438/724

(57) ABSTRACT

The present invention is to utilize chemical dry etching technique to form a rounded corner in a shallow trench isolation process. After finishing the etching of the shallow trench, the present invention utilizes an isotropic etching step, which is a chemical dry etching step of a high silicon nitride to silicon etching selectivity, to pullback the silicon nitride layer to expose a silicon top corner. Then, the present invention utilizes an isotropic etching step, which is a chemical dry etching step of a high silicon to silicon nitride etching selectivity, to make the corner rounded to obtain a rounded corner of the shallow trench isolation structure. The present invention can avoid the formation of wrap rounding of the corner and prevent the formation of the short circuit or extraordinary electric behavior between adjacent devices and supply for performing following processes.

### BACKGROUND OF THE INVENTION

1. Field of the Invention

The present invention generally relates to a method for etching in the semiconductor manufacture, and more particularly relates to a fabrication method for forming a rounded corner in a shallow trench isolation process by utilizing a chemical dry etching technique to pullpack the silicon nitride layer.

2. Description of the Prior Art

Accordingly, semiconductor device integration continuously increases with reduced device dimensions in an advanced integrated circuit manufacture; it is necessary to fabricate hundreds of thousand metal oxide semiconductor (MOS) transistors on a silicon surface with limited area. For the purpose to maintain operating with desired action between each MOS transistor, each MOS transistor of the integrated circuit on the substrate must be electrically isolated from the others to ensure their individual function and prevent a short circuit from occurring between adjacent devices. Field oxide is used to isolate active regions of adjacent devices. The most well known techniques for isolation process is the local oxidation of silicon (LOCOS) which provides the isolation by oxidizing the silicon substrate to create silicon dioxide regions among active devices or functional regions. Because of the benefits of its process simplicity, LOCOS becomes the most widely used isolation technique in 0.25 μm above MOS process. However, LOCOS isolation suffers from several drawbacks such as large lateral extend of bird's beak and field oxide thinning effect, so it could not use LOCOS for isolation in 0.25 μm below MOS process. After that, the trench isolation, which is usually referred as shallow trench isolation (STI), becomes the standard isolation technique. In general, comparison with LOCOS isolation, STI isolation process can improve the effect of large lateral extend of bird's beak in LOCOS isolation and have a better isolation planarity. Consequently, in the advanced MOS manufacture, STI isolation replaces LOCOS isolation to become the major isolation process to solve the problem of field oxide thinning effect causing from the bird's leak of LOCOS isolation.

In generally, the conventional STI structure is the sequential formation of a pad oxide layer and a silicon nitride layer on a silicon substrate. A photolithography step is then performed to form a patterned photoresist layer on the silicon nitride layer to define the etching region and utilizes etching technique to form a STI structure. For the purpose of avoiding a right angle profile of the corner of the STI structure, which increases the difficult for following processes, there are usually further formed a rounded profile of the silicon top corner of the STI structure. The common used method is to pullback the silicon nitride layer by wet etching technique or oxidation method to expose the edge portion of the silicon surface and then to form a rounded corner. However, disadvantage of common used method are complex and time-waste. Besides, in the conventional STI process, a high-density plasma (HDP) oxide layer is deposited into the shallow trench region and then a chemical vapor deposition is performed to form the STI structure. As a result of repeatedly performing wet chemical cleaning steps to remove the silicon nitride layer, it causes the warp rounding of the top corner of the STI structure. However, the wrap rounding effect will cause the oxide layer having incomplete coverage of the STI corner. So as in the next thermal oxidation process, the wrap rounding effect produces the non-uniform growth of oxide which it will generate the character of the parasitic devices, such as the double hump effect of the sub critical current, the high electric field effect, the pre-breakdown effect, and other unusual electric situations so as not to ensure their individual function of semiconductor devices.

Obviously, the main spirit of the present invention is to provide a fabrication method for forming a rounded corner by using chemical dry etching technique, and then some disadvantages of well-known technique are overcome.

### SUMMARY OF THE INVENTION

Accordingly, the primary object of the present invention is to utilize chemical dry etching technique to etch and pullback the silicon nitride layer to expose a silicon top corner and then perform an etching step to make the silicon top corner of the shallow trench isolation structure rounded and supply for performing following processes.

Another object of the present invention is to provide a fabrication method for forming a rounded corner of a shallow trench isolation structure to avoid the formation of wrap rounding of the corner after finishing the isolation process and prevent the formation of the short circuit or extraordinary electric behavior between adjacent devices.

A further object of the present invention is to provide a fabrication method for rapidly forming a rounded corner in the shallow trench isolation process and providing with an advantage of shortening and simplifying the process time.

Furthermore, another object of the present invention is to provide a method to pullback the silicon nitride layer by utilizing the chemical dry etching technique. Comparing with other methods which are using chemical dry etching pullback the silicon nitride layer in situ, the present invention provides a better efficiency of lateral side etching.

In order to achieve previous objects, the present invention provides a fabrication method for forming a rounded corner in a shallow trench isolation (STI) process by using chemical dry etching technique, wherein the fabrication method comprises following steps.

First, a silicon nitride layer is deposited on a substrate.

Then, a patterned photoresist layer is formed on the silicon nitride layer.

Using an etching process and using the patterned photoresist layer as a mask are to form a STI structure.

Following, chemical dry etching the STI structure with a high silicon nitride to substrate etching selectivity is performed to pullback the silicon nitride layer to expose a top surface of a corner of the STI structure.

Then, chemical dry etching the silicon nitride layer with a high substrate to silicon nitride etching selectivity is performed to form a rounded corner from the corner of the STI structure.

The present invention using the forgoing method can avoid the formation of wrap rounding of the corner after finishing the isolation process and prevent the formation of the short circuit or extraordinary behavior between adjacent devices supplying for performing following processes.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1, FIG. 2, FIG. 3, FIG. 4, and FIG. 5 are schematic representations structures at various stages during the formulation of a shallow trench isolation structure and its rounded corner, in accordance with one preferred embodiment of the present invention.

### DESCRIPTION OF THE PREFERRED EMBODIMENT

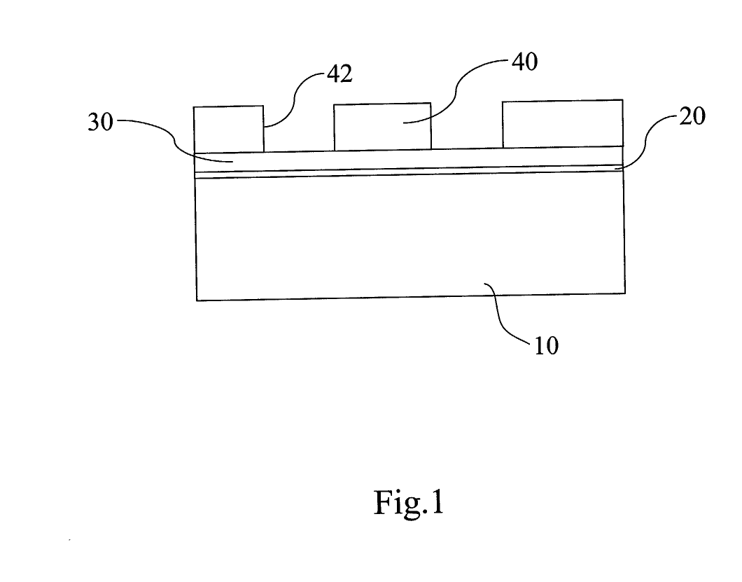

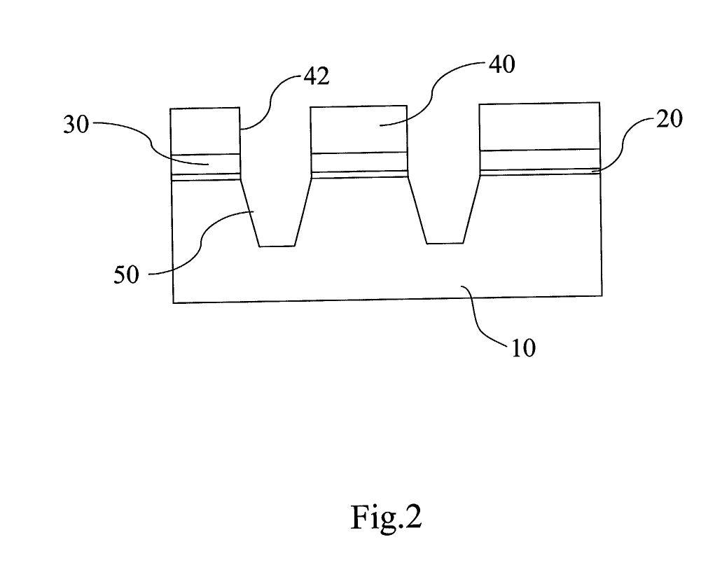

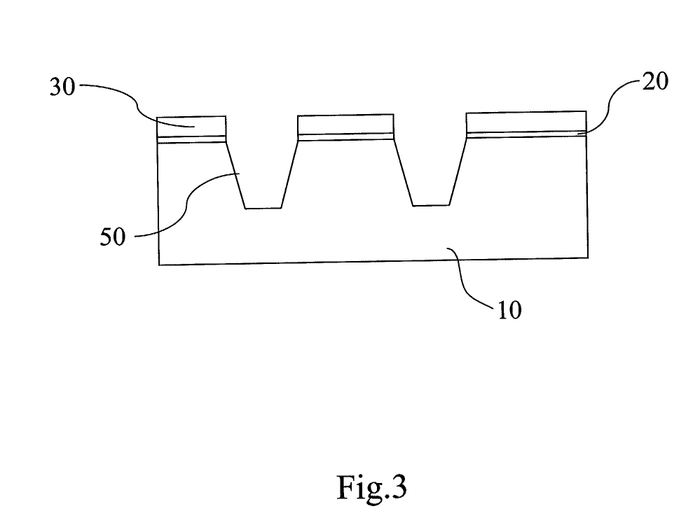

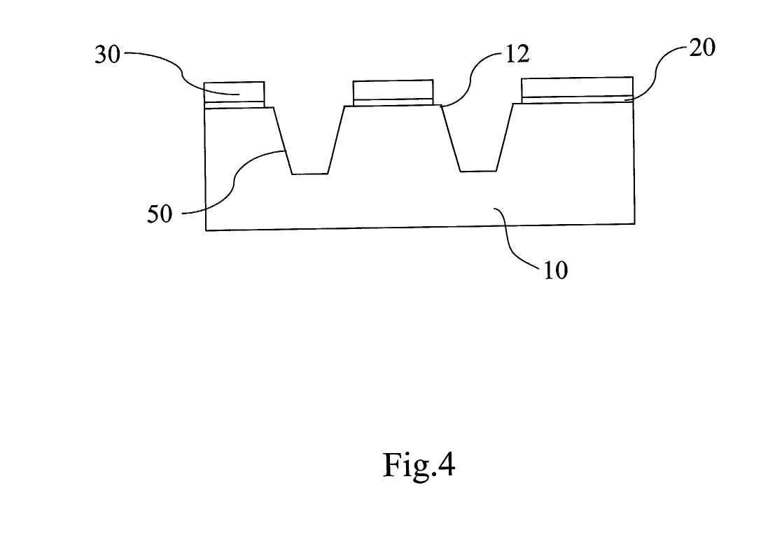

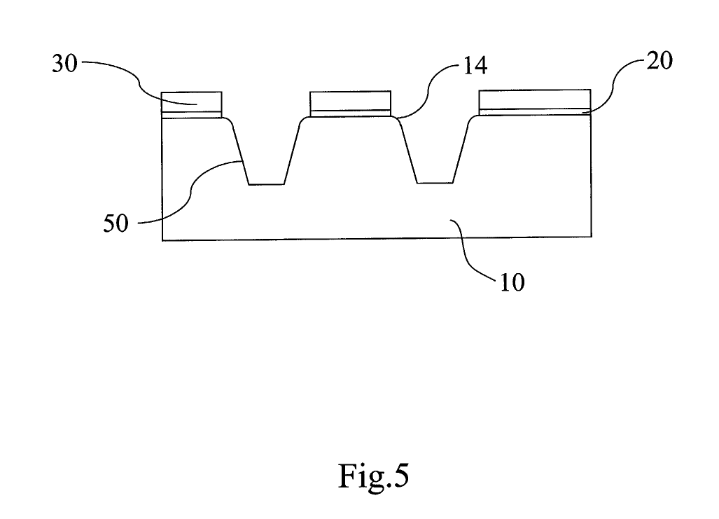

The present invention is to provide a method for forming a rounded corner in a shallow trench isolation process by using a chemical dry etching technique to pullback the silicon nitride layer. FIG. 1 to FIG. 5 are schematic representations structures at various stages during the formulation of a shallow trench isolation structure and its rounded corner, in accordance with one preferred embodiment of the present invention.

Referring to the FIG. 1, for the purpose to simplify the schematic representation structure, a semiconductor silicon substrate 10 having basic devices therein from preceding processes is provided, wherein some basic devices like MOS transistor in the semiconductor silicon substrate 10 are provisionally disregarded to detail shown herein. On the surface of the semiconductor silicon substrate 10, a pad oxide layer 20 is formed thereon by thermal oxidation deposition method, wherein the pad oxide layer is usually made of silicon dioxide, and then the pad oxide layer is planarized. Following, a silicon nitride layer 30 is deposited on the pad oxide layer 20 by furnace. Because the stress between the semiconductor silicon substrate 10 and the silicon nitride layer 30 is high, so the pad oxide layer 20 is usually used as a buffer layer to improve the high stress between the semiconductor silicon substrate 10 and the silicon nitride layer 30. Then, a photolithograph process comprising a step of coating a photoresist layer on the silicon nitride layer 30 and then a step of forming a patterned photoresist layer 40 is performed, wherein the patterned photoresist layer 40 has a etching window 42 with a appropriate size to define the size and location of the needed shallow trench region.

Consequently, after defining the size of the shallow trench, a shallow trench 50 is formed by using existing etching technique, such as shown in the FIG. 2, wherein the patterned photoresist layer 40 is serving as a mask to etch to remove the exposing portion from the etching window 42 of the silicon nitride layer 30 and the pad oxide layer 20 therebelow until reaching to etch a portion of the semiconductor silicon substrate 10 to form a shallow trench structure 50. After that, the patterned photoresist layer 40 is removed, such as shown in the FIG. 3. The etching gases that be used in the first step etching process are carbon tetra fluoride and oxygen (CF₄ and O₂), wherein the shallow trench 50 is formed by using anisotropic chemical dry etching technique, so the shallow trench 50 has almost a right angle profile of the corner.

Following the second step etching process, first, the present invention utilizes an anisotropic chemical dry etching process with a high silicon nitride to silicon etching selectivity to etch the edge of the silicon nitride layer 30 and the pad oxide layer 20 to pullback the silicon nitride layer 30 and the pad oxide layer 20, such as shown in the FIG. 4. Then, a almost right angle profile of a silicon corner 12 is exposed, wherein the etching gases that be used in the second step etching process are carbon tetra fluoride, oxygen and nitrogen (CF₄, O₂ and N₂). Besides, the etching selectivity of silicon nitride to silicon is larger than 1 (SiN/Si>1).

Finally, referring to the FIG. 5, the present invention utilizes an anisotropic chemical dry etching process with a high silicon to silicon nitride etching selectivity to round the right angle silicon corner 12 of the shallow trench structure 50 and then immediately a rounded corner 14 is formed at the top corner of the shallow trench 50. Besides, the etching selectivity of silicon to silicon nitride is larger than 1 (Si/SiN>1).

In sum of the forgoing, after the formation of the rounded corner of the shallow trench, the present invention can help for the following processes, such as deposition process, and can avoid the wrap rounding of the edge corner of the shallow trench and to prevent the unusual electric situations of the parasitic devices. Besides, the present invention uses the chemical dry etching technique to pullback the silicon nitride layer and has a short process time in comparison of conventional wet etching technique or oxidation method. Furthermore, the present invention provides with a better efficiency of lateral side etching in comparison of the in-situ method to pullback the silicon nitride layer by chemical dry etching technique.

The present invention can apply not only for the STI structure, but the present method also can solve other semiconductor processes requiring the etching step to form a rounded corner. The detail process steps can refer to the forgoing description and will not give detailed description herein again.

The forgoing description of the embodiments of the invention has been presented for purposes of illustration and description, and is not intended to be exhaustive or to limit the invention to he precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

What is claimed is:

1. A fabrication method for forming a rounded corner in a shallow trench isolation (STI) process by using chemical dry etching technique, said fabrication method comprising the steps of:
forming a silicon nitride layer on a substrate;
forming a patterned photoresist layer on said silicon nitride layer;
etching with said patterned photoresist layer serving as a mask to form a shallow trench structure;
chemical dry etching said silicon nitride layer with a high etching selectivity with respect to the substrate to pullback said silicon nitride layer to expose a top surface of the substrate at a corner of said shallow trench structure; and
chemical dry etching said the exposed substrate with a high etching selectivity with respect to the silicon nitride to form a rounded corner from said corner of said shallow trench structure.

2. The fabrication method according to claim 1, further comprises a step of forming a pad oxide layer between said substrate and said silicon nitride layer.

3. The fabrication method according to claim 1, wherein etching gases that be used in the step of chemical dry etching said STI structure are carbon tetra fluoride and oxygen (CF₄ and O₂).

4. The fabrication method according to claim 1, wherein said etching selectivity of silicon nitride to substrate is larger than 1.

5. The fabrication method according to claim 1, wherein etching gases that be used in the step of chemical dry etching said silicon nitride layer are carbon tetra fluoride, oxygen and nitrogen (CF₄, O₂ and N₂).

6. The fabrication method according to claim 1, wherein said etching selectivity of substrate to silicon nitride is larger than 1.

7. A fabrication method for forming a rounded corner by using chemical dry etching technique, said fabrication method comprising the steps of:
forming a silicon nitride layer on a silicon substrate;
forming a patterned photoresist layer on said silicon nitride layer;
etching with said patterned photoresist layer serving as a mask to form a patterned silicon nitride layer;
chemical dry etching said patterned silicon nitride layer with a high etching selectivity to the substrate to pullback said patterned silicon nitride layer to expose a top surface of a corner of said silicon substrate; and
chemical dry etching said the exposed substrate with a high etching selectivity with respect to silicon nitride to form a rounded corner from said corner of said silicon substrate.

8. The fabrication method according to claim 7, further comprises a step of forming a pad oxide layer between said silicon substrate and said silicon nitride layer.

9. The fabrication method according to claim 7, wherein etching gases that be used in the step of chemical dry etching said patterned silicon nitride layer are carbon tetra fluoride and oxygen (CF₄ and O₂).

10. The fabrication method according to claim 7, wherein said etching selectivity of silicon nitride to silicon is larger than 1.

11. The fabrication method according to claim 7, wherein etching gases that be used in the step of chemical dry etching said silicon nitride layer are carbon tetra fluoride, oxygen and nitrogen (CF₄, O₂ and N₂).

12. The fabrication method according to claim 7, wherein said etching selectivity of silicon to silicon nitride is larger than 1.
